(19) United States
(12) Patent Application Publication
(10) Pub. No.: US 2017/0186936 A1
(43) Pub. Date: Jun. 29, 2017

(54) PIEZOELECTRIC ELEMENT PRODUCTION METHOD THEREOF, ACTUATOR, AND LIQUID DISCHARGE APPARATUS

(71) Applicant: FUJIFILM Corporation, Tokyo (JP)

(72) Inventors: Takamichi FUJII, Kanagawa-ken (JP); Takehiro KASAHARA, Kanagawa-ken (JP)

(73) Assignee: FUJIFILM Corporation, Tokyo (JP)

(21) Appl. No.: 15/460,616

(22) Filed: Mar. 16, 2017

Related U.S. Application Data
(63) Continuation of application No. PCT/JP2015/004060, filed on Aug. 17, 2015.

(30) Foreign Application Priority Data
Sep. 30, 2014 (JP) 2014-201358

(51) Int. Cl. H01L 41/047; H01L 41/45; H01L 41/18; H01L 41/29; B41J 2/16; C23C 14/08

(52) U.S. Cl. CPC H01L 41/0477; B41J 2/1607; C23C 14/08; B41J 2/1646; H01L 41/18; H01L 41/29; H01L 41/45

(57) ABSTRACT

A piezoelectric element includes: a titanium-containing adhesion layer, a lower electrode, a PZT-based piezoelectric film, and an upper electrode, which are sequentially provided on a silicon substrate, in which the lower electrode includes a columnar structure film consisting of a large number of columnar crystals which are grown from a surface of the titanium-containing adhesion layer and have a platinum group element as a primary component, and an adhesion layer component diffused from the titanium containing adhesion layer and oxygen diffused from the piezoelectric film side, which are present in the columnar structure film, and a main column diameter of the columnar crystal of the columnar structure film is 50 nm or more and 200 nm or less.

### CROSS REFERENCE TO RELATED APPLICATIONS

The present application is a Continuation of PCT International Application No. PCT/JP2015/004060 filed on Aug. 17, 2015, which claims priority under 35 U.S.C. §119(a) to Japanese Patent Application No. 2014-201358 filed on Sep. 30, 2014. Each of the above applications is hereby expressly incorporated by reference, in its entirety, into the present application.

### BACKGROUND OF THE INVENTION

1. Field of the Invention

The present invention relates to a piezoelectric element provided with a lead zirconate titanate-based piezoelectric film and a production method thereof, an actuator using the piezoelectric element, and a liquid discharge apparatus.

2. Description of the Related Art

An actuator including an ink jet recording head is provided with a piezoelectric body having a piezoelectric property that expands and contracts with variation in applied electric field intensity, and a piezoelectric element provided with an electrode that applies an electric field to the piezoelectric body.

In recent years, in order to meet the demand for miniaturization of an apparatus, miniaturization of an actuator in cooperation with a semiconductor process technology such as a microelectromechanical systems (MEMS) technology has proceeded. In the semiconductor process technology, high-precision processing using film formation or photolithography becomes possible. Therefore, there has been actively conducted research on thinning of a piezoelectric body in an actuator.

As a piezoelectric material having high piezoelectric properties, a lead zirconate titanate (PZT)-based perovskite oxide has been widely used due to its performance. It is known that when a PZT-based perovskite oxide piezoelectric film has a morphotropic phase boundary (MPB) composition in which Zr:Ti is near 52:48, the piezoelectric constant and the electromechanical coupling coefficient thereof become maximum, which is appropriate for actuator applications.

In JP2012-99636A, it is described that in a piezoelectric element provided with a piezoelectric thin film having a laminate of a lead titanate layer and a lead zirconate layer, which have columnar structures, the compositions of lead titanate and lead zirconate in the piezoelectric thin film are caused to be MPB compositions, thereby improving piezoelectric properties.

On the other hand, as a technique for improving piezoelectric properties using a method other than that for the formation of the MPB compositions, doping a PZT-based piezoelectric film with various donor ions having higher valences than those of substituted ions is known. Since the ionic valence of Zr and Ti in B-site is 4, as donor ions that substitute for B-site elements, B-site elements having an ionic valence of 5 or higher, such as V, Nb, Ta, Sb, Mo, and W have been used.

For example, in JP1995-48172A (JP-H07-48172A), a composition for a PZT-based actuator, in which A-site of PZT is doped with Sr, Ba, and/or La and B-site is doped with Sb or Nb, resulting in a composition closer to a rhombohedron side than a MPB composition is disclosed. In JP1995-48172A (JP-H07-48172A), it is described that a laminated actuator which uses a rhombohedral crystal system PZT-based composition has excellent characteristics and causes a low degree of deterioration in displacement characteristics in durable use.

Attempts on donor ion doping have been examined in thin film applications. In JP2005-209722A, it is described that in order to dope a PZT-based ferroelectric film with Nb as B-site ions at a high concentration, at least one of Si, Ge, and Sn is added as A-site ions. In JP2005-209722A, compensation ions added to the A-site are a sintering aid for obtaining a thermal equilibrium state by accelerating sintering in a thermal equilibrium process by a sol-gel method, and are necessary for suppressing an increase in crystallization temperature due to the Nb doping. However, when the sintering aid is added, piezoelectric properties deteriorate, and the effect of the addition of donor ions cannot be sufficiently exhibited.

An attempt to dope PZT with Nb at a high concentration without the use of a sintering aid has been reported by the inventors. In JP2008-270704A, a Nb-doped PZT film in which the effect of the addition of donor ions is significantly exhibited by controlling film formation conditions in a non-thermal-equilibrium process is described. In JP2008-270704A, the production of the Nb-doped PZT film having a MPB composition succeeded.

On the other hand, in a piezoelectric element provided with a piezoelectric film, an electrode made of a platinum metal element such as Pt or Ir is used as a lower electrode. The adhesiveness between the lower electrode and a silicon substrate or the piezoelectric film is poor, and there is a problem that peeling between the adjacent layers easily occurs.

In JP2007-281238A, a production method of a piezoelectric element having processes of forming a seed layer including a constituent element of a piezoelectric film between a substrate and a lower electrode, and diffusing the constituent element of the piezoelectric film from the seed layer before the formation of the piezoelectric film to cause the element to be precipitated to the surface of the lower electrode is disclosed.

In JP2007-281238A, it is described that the seed layer functions as an adhesion layer between the substrate and the lower electrode.

### SUMMARY OF THE INVENTION

However, peeling between an electrode and a piezoelectric film is a problem regarding element reliability, and thus higher adhesiveness is required. In the configuration of JP2007-281238A, it is thought that an effect of improving the adhesiveness between the substrate and the lower electrode is obtained. However, an effect of improving the adhesiveness between the lower electrode and the piezoelectric film is not described.

In addition, the piezoelectric element using the Nb-doped PZT film has higher film stress on the piezoelectric film than a piezoelectric element using an intrinsic PZT film, and thus has a problem that the lower electrode and the piezoelectric film easily peel away from each other. In addition, due to high piezoelectric properties, high stress is applied to the interface between the substrate and the lower electrode during driving, and there is a problem in that the substrate and the lower electrode more easily peel away from each other.

The present invention has been made taking the foregoing circumstances into consideration, and an object thereof is to provide a PZT-based piezoelectric element having high adhesiveness between a substrate and a lower electrode, high adhesiveness between the lower electrode and a piezoelectric film, and excellent long-term driving reliability, and a production method thereof.

Another object of the present invention is to provide an actuator and a liquid discharge apparatus each including a PZT-based piezoelectric element having high adhesiveness between a substrate and a lower electrode, high adhesiveness between the lower electrode and a piezoelectric film, and excellent long-term driving reliability.

A piezoelectric element of the present invention comprises: a titanium-containing adhesion layer, a lower electrode, a piezoelectric film including a perovskite oxide represented by the following general formula (P), and an upper electrode, which are sequentially provided on a silicon substrate,

in which the lower electrode includes a columnar structure film including a large number of columnar crystals which are grown from a surface of the titanium-containing adhesion layer and have a platinum group element as a primary component, and an adhesion layer component diffused from the titanium-containing adhesion layer and oxygen diffused from the piezoelectric film side, which are present in the columnar structure film, and

a main column diameter of the columnar crystal of the columnar structure film is 50 nm or more and 200 nm or less,

Aₐ(Zrₓ,Ti_{y},M_{b-x-y})_{b}O_{c} (P)

in the formula, A is an element in A-site and is at least one element including Pb, M is one or two or more metal elements, 0<x<b, 0<y<b, and 0≦b-x-y are satisfied, and a:b:c=1:1:3 is standard, and the molar ratio may be deviated from the standard value in a range in which a perovskite structure is able to be obtained.

In this specification, the main column diameter represents the main diameter of the diameter of columns observed from a cross-section transmission electron microscope image (hereinafter, referred to as cross-section TEM image) or a cross-section scanning electron microscope image (hereinafter, referred to as cross-section SEM image) in a range in which several crystal columns are seen. The measurement position at this time is preferably the center portion of a film thickness as a position in the film thickness direction. The main diameter may be in the range and may be deviated from the range at a rare frequency.

In this specification, “the primary component” means a component in a proportion of 90 mol % or more.

In the piezoelectric element of the present invention, it is preferable that titanium and the oxygen in the columnar structure film are bonded together.

In addition, it is preferable that an oxide layer of the platinum group element that forms the lower electrode is formed on the surface of the lower electrode on the piezoelectric film side. It is preferable that a thickness of the oxide layer is 20 nm or less.

It is preferable that the platinum group element that forms the lower electrode is iridium.

In addition, the titanium-containing adhesion layer is preferably a metal layer, and more preferably a titanium layer or a titanium tungsten layer.

It is preferable that the piezoelectric film includes the perovskite oxide which includes Nb as the M in the general formula (P).

The piezoelectric element of the present invention is particularly suitable for a case where a stress of the piezoelectric film is 120 MPa or higher. In addition, the piezoelectric element of the present invention is suitable for an actuator or a liquid discharge apparatus.

A actuator of the present invention comprises the piezoelectric element of the present invention. In addition, a liquid discharge apparatus of the present invention comprises: the piezoelectric element of the present invention; and a liquid discharge member which is provided integrally with or separately from the piezoelectric element, in which the liquid discharge member has a liquid storage chamber which stores a liquid, and a liquid discharge port through which the liquid is discharged from the liquid storage chamber to the outside.

A production method of a piezoelectric element of the present invention is a production method of a piezoelectric element in which a titanium-containing adhesion layer, a lower electrode including a columnar structure film that has a main column diameter of 50 nm or more and 200 nm or less and has a platinum group element as a primary component, a piezoelectric film including a perovskite oxide represented by the following general formula (P), and an upper electrode, which are sequentially provided on a silicon substrate, the method comprising:

a lower electrode forming process of sequentially forming, on the silicon substrate, the titanium-containing adhesion layer and the lower electrode;

an oxygen diffusion process of diffusing oxygen from the surface side of the lower electrode into the lower electrode; and

a piezoelectric film forming process of forming the piezoelectric film on the surface of the lower electrode through a sputtering method,

Aₐ(Zrₓ,Ti_{y},M_{b-x-y})_{b}O_{c} (P)

in the formula, A is an element in A-site and is at least one element including Pb, M is one or two or more metal elements, 0<x<b, 0<y<b, and 0≦b-x-y are satisfied, and a:b:c=1:1:3 is standard, and the molar ratio may be deviated from the standard value in a range in which a perovskite structure is able to be obtained. In addition, the structure is not confined to a crystal system.

Here, “a lower electrode including a columnar structure film that has a main column diameter of 50 nm or more and 200 nm or less and has a platinum group element as a primary component” means that the main column diameter of a large number of the columnar crystals constituting the columnar structure film having the platinum group element as the primary component is 50 nm or more and 200 nm or less.

It is preferable that the oxygen diffusion process is a process of causing oxygen gas to flow onto the surface of the lower electrode.

In addition, it is preferable that a constituent element of the titanium-containing adhesion layer is diffused into the lower electrode to precipitate the constituent element on the surface of the lower electrode before performing the piezoelectric film forming process.

The piezoelectric element of the present invention sequentially includes, on the silicon substrate, the titanium-containing adhesion layer, the lower electrode, and the piezoelectric film including the PZT-based perovskite oxide represented by the general formula (P), and the adhesion layer component diffused from the adhesion layer and the oxygen diffused from the piezoelectric film side are included in the columnar structure film having the platinum group element of the lower electrode as the primary component. In this configuration, since high adhesiveness between the substrate and the lower electrode and high adhesiveness between the lower electrode and the piezoelectric film are achieved, peeling between the substrate and the electrodes and between the electrodes and the piezoelectric film is less likely to occur during long-term driving. Therefore, according to the present invention, the PZT-based piezoelectric element having excellent long-term driving reliability can be provided.

In addition, according to the production method of the piezoelectric element of the present invention, since the oxygen diffusion process is performed before the formation of the piezoelectric film, the PZT-based piezoelectric element having high adhesiveness between the substrate and the lower electrode, high adhesiveness between the lower electrode and the piezoelectric film, and excellent long-term driving reliability can be easily produced.

### BRIEF DESCRIPTION OF THE DRAWINGS

FIG. 1 is a sectional view of main parts, illustrating the structures a piezoelectric element of an embodiment according to the present invention, and an ink jet recording head including the same.

FIG. 2A is a view illustrating a lower electrode forming process in a production method of the piezoelectric element of the embodiment according to the present invention.

FIG. 2B is a view illustrating an oxygen diffusion process in the production method of the piezoelectric element of the embodiment according to the present invention.

FIG. 2C is a view illustrating a piezoelectric film forming process in the production method of the piezoelectric element of the embodiment according to the present invention.

FIG. 2D is a view illustrating a patterning process in the production method of the piezoelectric element of the embodiment according to the present invention.

FIG. 2E is a view illustrating an upper electrode forming process in the production method of the piezoelectric element of the embodiment according to the present invention.

FIG. 3 is a view illustrating an example of the configuration of an ink jet recording device provided with the ink jet recording head of FIG. 1.

FIG. 4 is a partial top view of the ink jet recording device of FIG. 3.

FIG. 5 is a view showing a cross-section TEM image after formation of an Ir lower electrode in Example 1.

FIG. 6 is a view showing a cross-section TEM image (HAADF-STEM image) according to high-angle annular dark-field scanning transmission electron microscopy in the vicinity of the Ir lower electrode of a laminate formed up to an Nb-doped PZT film in Example 1.

FIG. 7 is a mapping diagram of a HAADF-STEM image of FIG. 6 at Point 1 and Point 2 according to electron energy loss spectroscopy (EELS).

FIG. 8 is a view showing a HAADF-STEM image in the vicinity of the interface between the Ir lower electrode and PZT of the laminate formed up to the Nb-doped PZT film in Example 1.

FIG. 9 is a view showing a cross-section SEM image after the film formation of an Ir lower electrode in Example 2.

FIG. 10 is a view showing a cross-section SEM image after the film formation of an Ir lower electrode in Comparative Example 1.

### DESCRIPTION OF THE PREFERRED EMBODIMENTS

“Piezoelectric Element, Actuator, and Ink Jet Recording Head”

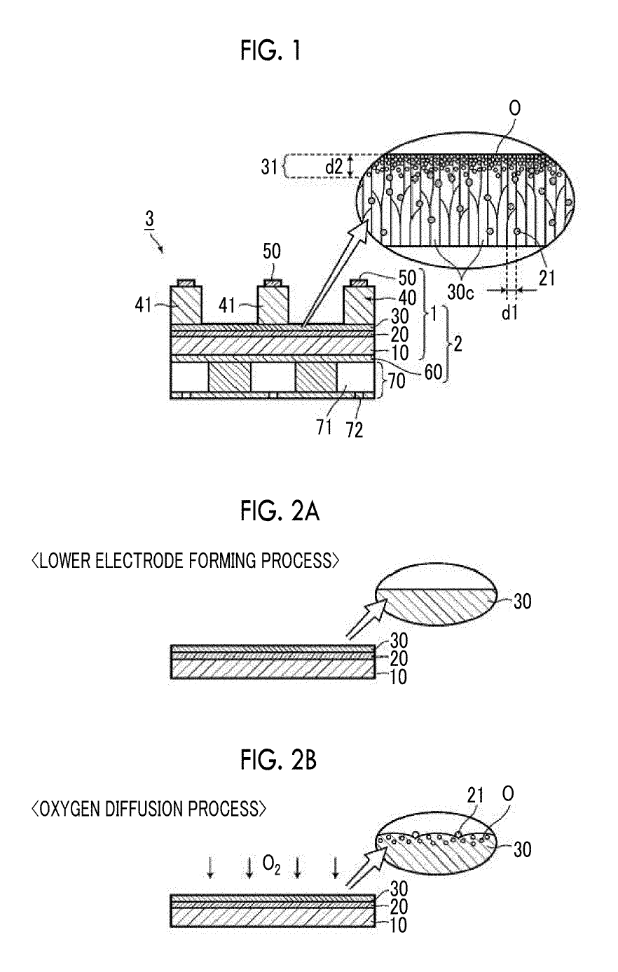

The structures of a piezoelectric element of an embodiment according to the present invention, and an actuator and an ink jet recording head (liquid discharge apparatus) each including the same will be described with reference to FIG. 1. FIG. 1 is a sectional view of main parts of the ink jet recording head (a sectional view of the piezoelectric element in a thickness direction). For ease of viewing, the scales of the constituent elements are appropriately changed from actual scales.

A piezoelectric actuator 2 of this embodiment is formed by attaching a diaphragm 60, which vibrates due to expansion and contraction of a piezoelectric film 40, to the rear surface of a substrate 10 of a piezoelectric element 1 in which a titanium-containing adhesion layer 20, a lower electrode 30, the piezoelectric film 40, and an upper electrode 50 are sequentially laminated on the substrate 10. In the piezoelectric element 1, an electric field is applied in a film thickness direction to the piezoelectric film 40 by the lower electrode 30 and the upper electrode 50, and in the piezoelectric actuator 2, control means (not illustrated) such as a driving circuit for controlling driving of the piezoelectric element 1 is also provided.

In this embodiment, the titanium-containing adhesion layer 20 and the lower electrode 30 are sequentially laminated on substantially the entire surface of the substrate 10, the piezoelectric film 40 having a pattern in which line-shaped protruding portions 41 extending from the front side to the rear side in the figure are arranged in a stripe shape is formed on the lower electrode 30, and the upper electrode 50 is formed on each of the protruding portions 41.

The pattern of the piezoelectric film 40 is not limited to the illustrated pattern and is appropriately designed. In addition, the piezoelectric film 40 may also be a continuous film. However, by forming the piezoelectric film 40 in the pattern consisting of the plurality of protruding portions 41 which are separated from each other instead of a continuous film, expansion and contraction of the individual protruding portions 41 smoothly occur, and a greater displacement amount is obtained, which is preferable.

In the ink jet recording head (liquid discharge apparatus) 3, an ink nozzle (liquid storage and discharge member) 70 having ink chambers (liquid storage chambers) 71 that store ink and ink discharge ports (liquid discharge ports) 72 through which the ink is discharged from the ink chambers 71 to the outside is attached to the lower surface of the substrate 10 of the piezoelectric element 1 having configuration schematically described above, via the diaphragm 60. A plurality of the ink chambers 71 are provided to correspond to the number and pattern of the protruding portions 41 of the piezoelectric film 40.

In the ink jet recording head 3, the intensity of an electric field applied to the protruding portions 41 of the piezoelectric element 1 is varied with the protruding portions 41 so as to cause the protruding portions 41 to expand and contract, such that the discharge of the ink from the ink chambers 71 and the discharge amount thereof are controlled.

In actuator applications including an ink jet recording head, as the piezoelectric constant of a piezoelectric film increases, the displacement amount of the piezoelectric film increases. Accordingly, for a piezoelectric element in which a plurality of layers are laminated and formed on a substrate, an improvement in the adhesiveness between the layers becomes more important from the viewpoint of element reliability.

As described in the sections “Description of the Related Art” and “SUMMARY OF THE INVENTION”, particularly in a configuration in which a lower electrode having a platinum metal element such as Pt or Ir as the primary component is used as the lower electrode, the adhesiveness between the lower electrode and the substrate or the adhesiveness between the lower electrode and the piezoelectric film is poor, and the layers vertically adjacent to the lower electrode easily peel.

Furthermore, an Nb-doped PZT film, which is currently regarded as having a high piezoelectric constant, has not only a high piezoelectric constant but also higher film stress, which is thought to be caused by a difference in thermal expansion coefficient from a silicon substrate, than intrinsic PZT in the related art, and thus requires a higher level of adhesiveness between the layers of a laminate than the intrinsic PZT.

The inventors had paid attention to the fact that a lower electrode having a platinum metal element such as platinum (Pt) or iridium (Ir) as the primary component can have a columnar structure film, and succeeded in causing interdiffusion of titanium (Ti) from a titanium-containing adhesion layer as the underlayer and oxygen from the overlayer into the lower electrode through the grain boundaries between columnar crystals constituting the columnar structure film, thereby causing an interaction between the lower electrode, the underlayer, and the overlayer, and improving the adhesiveness therebetween.

That is, the piezoelectric element 1 sequentially has the titanium-containing adhesion layer 20, the lower electrode 30, the piezoelectric film 40 including a perovskite oxide represented by the following general formula (P), and the upper electrode 50 on the silicon substrate 10, in which

the lower electrode 30 includes a columnar structure film consisting of a large number of columnar crystals 30c which are grown from the surface of the titanium-containing adhesion layer 20 and have a platinum group element as the primary component, and a adhesion layer component 21 diffused from the titanium-containing adhesion layer 20 and oxygen (O) diffused from the piezoelectric film side, which are present in the columnar structure film, and the main column diameter d1 of the columnar crystal 30c of the columnar structure film is 50 nm or more and 200 nm or less.

Aₐ(Zrₓ,Ti_{y},M_{b-x-y})_{b}O_{c} (P)

in the formula, A is an element in A-site and is at least one element including Pb, and M is one or two or more metal elements. 0<x<b, 0<y<b, and 0≦b-x-y are satisfied, and a:b:c=1:1:3 is standard. However, the molar ratio may be deviated from the standard value in a range in which a perovskite structure is able to be obtained.

In this configuration, in a case where the adhesion layer component 21 diffused from the titanium-containing adhesion layer 20 and the oxygen (O) diffused from the piezoelectric film 40 side are bonded together in the lower electrode 30 and form titanium oxide, a significant interaction is caused between the lower electrode 30 and the titanium-containing adhesion layer 20 and the piezoelectric film 40, which are the upper and lower adjacent layers. Therefore, the adhesiveness between the lower electrode 30 and the upper and lower adjacent layers becomes strong, which is preferable.

The titanium-containing adhesion layer 20 is not particularly limited as long as the layer is a layer containing titanium (Ti). However, a metal layer is preferable, and a titanium (Ti) layer or a titanium tungsten (TiW) layer is more preferable. The titanium content in the titanium-containing adhesion layer 20 is preferably at least 10 mol % or more.

It is preferable that the columnar structure film which forms the lower electrode 30 and consists of the large number of columnar crystals 30c, which are grown from the surface of the titanium-containing adhesion layer 20 and have the platinum metal element as the primary component, has iridium as the primary component.

In addition, in the piezoelectric element 1, an oxide layer 31 of the constituent metal of the lower electrode 30 is formed into a film thickness of d2 from the surface of the lower electrode 30 in which the oxide layer 31 is formed. In this configuration, the piezoelectric film 40 achieves better crystallinity, which is preferable. Details will be described later.

The perovskite oxide represented by the general formula (P) is a PZT-based perovskite oxide, and M in the formula means a B-site dopant. As the perovskite oxide represented by the general formula (P), there are lead titanate, lead zirconate titanate (PZT), lead zirconium niobate titanate, and lead lanthanum zirconate titanate. The piezoelectric film may also be a mixed crystal system of the perovskite oxides represented by the general formula (P).

The ratio between Zr and Ti in the general formula (P) is not particularly limited, and is preferably the ratio of a morphotropic phase boundary (MPB) composition because a high piezoelectric constant is achieved. The ratio of the MPB composition is x:y=52:48.

From the viewpoint of the improvement in piezoelectric properties, the dopant M preferably include B-site elements such as such as Group VA, Group VB, Group VIA, and Group VIB. As described above, in a case where M is Nb, higher piezoelectric properties are achieved, which is preferable. In particular, a PZT sputtered film doped with Nb at a high concentration without the addition of a sintering aid is more preferable because an effect of improving piezoelectric properties by Nb doping is effectively exhibited. Such a piezoelectric film in a piezoelectric element receives a stress of 120 MPa or higher. Since the piezoelectric element 1 has high adhesiveness between the lower electrode 30 and the underlayer and the overlayer thereof, a greater effect can be exhibited in a case where higher stress is applied and a piezoelectric film having high piezoelectric properties is provided. Elements that may increase performance may also be appropriately added.

The film thickness of the piezoelectric film 40 is not particularly limited, and is preferably 0.5 μm or more and 10 μm or less, and more preferably 1 to 5 μm. By providing a piezoelectric film in this film thickness range, piezoelectric performance can be sufficiently exhibited, and a problem such as significant warping of a substrate due to excessive stress is less likely to be incurred.

Regarding the PZT-based perovskite oxide, there are three types of crystal systems including a cubic crystal system, a tetragonal crystal system, and a rhombohedral crystal system. Since the cubic crystal system is a paraelectric body and shows no piezoelectric properties, the piezoelectric film 40 needs to have either a tetragonal crystal system or a rhombohedral crystal system. In consideration of the coincidence between the spontaneous polarization axis and the electric field application direction, it is most preferable that the piezoelectric film 40 is preferentially oriented in the (100) plane in a case of having a tetragonal crystal structure, and is preferentially oriented in the (111) plane or in the (100) plane in a case of having a rhombohedral crystal structure. Pseudocubic crystals may also be included in the film.

By forming a film of the PZT-based perovskite oxide through a sputtering method, a perovskite oxide film which is preferentially oriented in the (100) plane can be formed.

The primary component of the upper electrode 50 is not particularly limited, and may include materials exemplified for the lower electrode 30, electrode materials generally used in a semiconductor process such as Al, Ta, Cr, and Cu, and a combination thereof.

As described above, in the piezoelectric element 1, the lower electrode 30 having a platinum metal element such as Pt or Ir as the primary component is caused to be the columnar structure film, and an interaction between the lower electrode and the underlayer and the overlayer thereof is caused by interdiffusion of titanium from the titanium-containing adhesion layer as the underlayer and oxygen from the overlayer into the columnar structure film, thereby improving the adhesiveness therebetween. The lower electrode 30 includes, in the columnar structure film having the platinum metal element as the primary component, titanium (Ti) diffused from the titanium-containing adhesion layer 20 and oxygen (O) diffused from the piezoelectric film side, and the main column diameter of the columnar crystal 30c of the columnar structure film is 50 nm or more and 200 nm or less.

The lower electrode 30 can be easily produced by a production method of the piezoelectric element of the present invention described below.

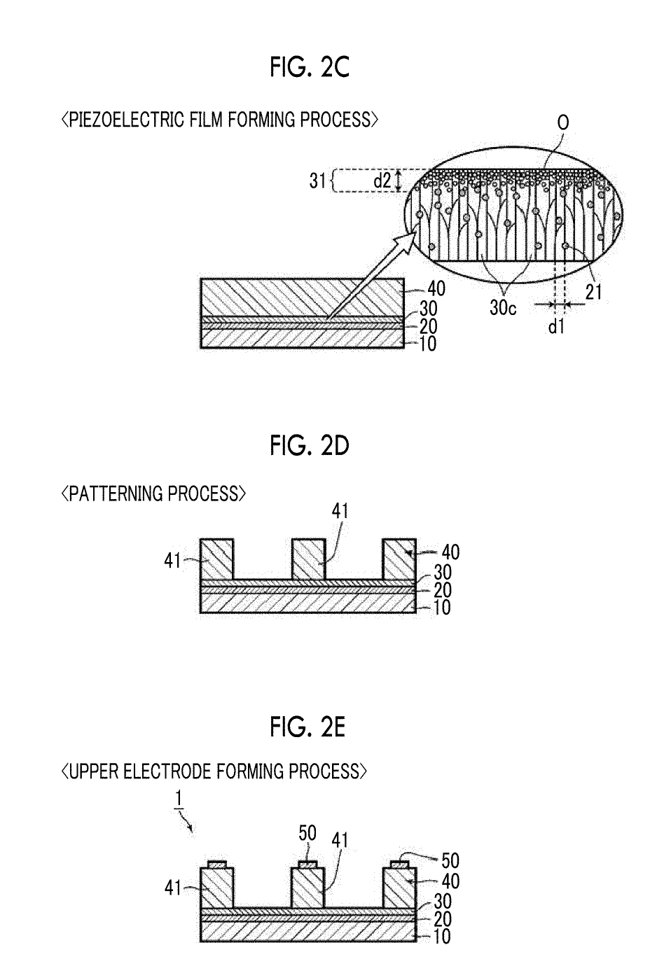

FIGS. 2A to 2E schematically show a flow of the production method of the piezoelectric element of the present invention using a schematic sectional view of each process. The production method of the piezoelectric element of the present invention has

a lower electrode forming process of sequentially forming, on the silicon substrate 10, the titanium-containing adhesion layer 20 and the lower electrode 30 consisting of the columnar structure film, which has a main column diameter of 50 nm or more and 200 nm or less and has the platinum group element as the primary component,

an oxygen diffusion process of diffusing oxygen from the surface side of the lower electrode 30 into the lower electrode 30, and

a piezoelectric film forming process of forming the piezoelectric film 40 on the surface of the lower electrode 30 through a sputtering method.

<Lower Electrode Forming Process>

As illustrated in FIG. 2A, the silicon substrate 10, which is a silicon substrate, a silicon on insulator (SOI) substrate in which a SiO₂ film is formed on the surface of a silicon substrate, or the like is prepared, and the titanium-containing adhesion layer 20 and the lower electrode 30 are sequentially formed on substantially the entire surface on the substrate. As illustrated in an enlarged view in FIG. 2A, the surface of the lower electrode 30 at this time is substantially flat, and the average surface roughness Ra thereof is, for example, less than 0.5 nm.

A method of forming the titanium-containing adhesion layer 20 and the lower electrode 30 is not particularly limited as long as the lower electrode 30 is caused to be the columnar structure film including a large number of the columnar crystals, which are grown from the surface of the titanium-containing adhesion layer and have a main column diameter of 50 nm or more and 200 nm or less, and is preferably a sputtering method. The formation of the titanium-containing adhesion layer 20 and the lower electrode 30 may be performed using the same apparatus or may be performed using different apparatuses. In this process, it is preferable to form the titanium-containing adhesion layer 20 into a thickness of 5 to 50 nm and form the lower electrode 30 into a thickness of 50 to 500 nm.

The columnar structure film of the lower electrode 30 is a columnar structure film consisting of a large number of the columnar crystals 30c which are grown from the surface of the titanium-containing adhesion layer 20, and the main column diameter of the large number of columnar crystals 30c is 50 nm or more and 200 nm or less. By achieving this main column diameter, in the subsequent process, titanium in the titanium-containing adhesion layer and oxygen can be favorably diffused into the columnar structure film.

In addition, in a case where the large number of columnar crystals 30c are grown in the film thickness direction from the surface of the titanium-containing adhesion layer 20, diffusion of titanium from the titanium adhesion layer and diffusion of oxygen in the subsequent process easily occur, which is preferable.

Therefore, the film formation conditions of the lower electrode 30 are preferably set to conditions under which the large number of columnar crystals 30c having the above-mentioned column diameters are grown in the film thickness direction from the surface of the titanium-containing adhesion layer 20. In the sputtering method, control of the growth direction and the main column diameter of the columnar crystals may be performed by a well-known method. For example, during film formation according to the sputtering method, as the distance between a substrate and a target increases and the film formation temperature decreases, the main column diameter of the columnar crystals of a columnar structure film decreases. Besides, the main column diameter may also be controlled by the film formation pressure. In a case where the lower electrode 30 has iridium (Ir) as the primary component, the above-described range of the main column diameter of the columnar crystals can be easily achieved through the film formation according to the sputtering method, which is preferable.

<Oxygen Diffusion Process>

Next, as illustrated in FIG. 2B, oxygen is diffused from the upper surface (surface) of the lower electrode 30 into the lower electrode 30. An oxygen diffusion method is not particularly limited, and a method of causing oxygen gas to flow onto the surface of the lower electrode 30 is preferable. In particular, since the formation of the piezoelectric film in the subsequent process is performed through a sputtering method, a method of causing oxygen gas to flow into a sputtering chamber is simple.

As for the flowing conditions of the oxygen gas, it is preferable to cause the flowing of the oxygen gas at a substrate temperature of 400 degrees or higher. The amount of flowing oxygen gas is dependent on the configuration of the apparatus, but the partial pressure thereof is preferably 1×10⁻³ Pa or higher. At this time, Ar gas may be caused to flow at the same time. The flowing time may be 30 seconds or longer. However, when the flowing time is 5 minutes or longer, the processing time increases, which is not preferable. In addition, when the flowing temperature of the oxygen gas is set to be the same as the film formation temperature of the piezoelectric film 40 in the subsequent process, there is no need to change the set temperature at the time of the start of film formation of the piezoelectric film 40, and thus the film formation efficiency increases, which is preferable.

In order to form a high-quality PZT-based piezoelectric film, it is preferable that precipitates 21 including the adhesion layer component of the titanium-containing adhesion layer 20 are precipitated to the surface of the lower electrode 30 before performing the piezoelectric film forming process. An enlarged view in FIG. 2B illustrates a form in which oxygen is diffused to the vicinity of the surface of the lower electrode 30 during the oxygen diffusion process and the precipitates 21 including the adhesion layer component of the titanium-containing adhesion layer 20 are further precipitated to the surface of the lower electrode 30.

The film formation temperature of the piezoelectric film in the subsequent process is preferably 400° C. to 700° C., and particularly preferably 450° C. to 650° C. In a case where the above temperature is set, by causing the flowing time of the oxygen gas to be in a range of 1 minute to 5 minutes, diffusion of oxygen into the lower electrode 30 and precipitation of the precipitates 21 can be sufficiently completed in this oxygen diffusion process. The flowing time of the oxygen gas may be appropriately set depending on the conditions such as the thickness of the lower electrode 30 and the main column diameter of the columnar crystals of the columnar structure film forming the lower electrode 30.

Precipitation of the precipitates 21 may be performed in a different process from the oxygen diffusion process. In this case, the oxygen diffusion process time can be shortened. In this case, it is preferable to perform the precipitation process of the precipitates 21 before the oxygen diffusion process. The process is preferably a heating process through light irradiation as well as a typical heat treatment using a heater.

As illustrated in the enlarged view in FIG. 2B, it is confirmed that at the time of the end of the oxygen diffusion process, fine unevenness is generated on the surface of the lower electrode 30. In a case where the average surface roughness Ra of the lower electrode 30 after the end of the oxygen diffusion process is 0.5 to 30.0 nm, a piezoelectric film with better crystallinity can be formed in the subsequent process.

In addition, diffusion of oxygen also proceeds even during the piezoelectric film forming process as the subsequent process. At this time, there is a possibility that the diffusion of oxygen that proceeds may include not only the diffusion of oxygen diffused into the lower electrode 30 but also the diffusion of oxygen introduced into the lower electrode 30 during the piezoelectric film forming process.

<Piezoelectric Film Forming Process>

Next, as illustrated in FIG. 2C, the piezoelectric film 40 is formed on the surface of the lower electrode 30 through a sputtering method. Before the piezoelectric film forming process, the precipitates 21 are scattered on the surface of the lower electrode 30. In the piezoelectric film forming process, the precipitates 21 become the nuclei of crystal growth, and crystals of the perovskite oxide are grown. Therefore, the piezoelectric film 40 having excellent crystal orientation and excellent piezoelectric performance can be formed.

An enlarged view in FIG. 2C schematically illustrates the configuration of the lower electrode 30 after the end of the piezoelectric film forming process. As illustrated, the lower electrode 30 includes, in the columnar structure film constituted by the large number of columnar crystals 30c having a main column diameter d1 of 50 nm or more and 200 nm or less, the precipitates 21 including the adhesion layer component diffused from the titanium-containing adhesion layer 20 and oxygen diffused from the piezoelectric film 40 side.

As illustrated, the oxygen diffused from the piezoelectric film 40 is present at the highest concentration in the vicinity of the surface of the lower electrode 30 on the piezoelectric film 40 side and is present with a concentration gradient such that the concentration decreases toward the substrate side. In the lower electrode 30, the thickness d2, which represents the amount of diffused oxygen, is preferably 50 nm or more.

When the oxygen diffused from the piezoelectric film 40 side and the adhesion layer component diffused from the titanium-containing adhesion layer 20 meet in the lower electrode 30, the adhesion layer component and the oxygen are bonded together and form oxide of the adhesion layer component (titanium oxide in a case where the diffused adhesion layer component is titanium). When the oxide is formed, the adhesiveness between the lower electrode 30 and the underlayer and the overlayer thereof becomes stronger, which is preferable. In addition, in a case where the adhesion layer is a TiW layer, there may be cases where W diffuses in a larger proportion than Ti although this is dependent on the composition and crystallinity.

Furthermore, since the oxygen diffused from the piezoelectric film 40 side is present at the highest concentration in the vicinity of the surface of the lower electrode 30 on the piezoelectric film 40 side, metal in the lower electrode 30 enter an oxidized state, and the oxide layer 31 of the constituent metal of the lower electrode 30 may be formed. In a form in which the oxide layer is formed, the average surface roughness Ra of the surface of the lower electrode 30 is more likely to have a larger value on the larger value side within a range of 0.5 to 30.0 nm. It is not clear whether this is the main cause or not, but it has been confirmed that the crystallinity of the piezoelectric film 40 is improved in a case where this oxide layer is formed. This oxide layer is preferably present in a range of 20 nm or less. The surface roughness Ra mentioned here is a value based on JIS B 0601-1994.

Last, as illustrated in FIG. 2D, by patterning the piezoelectric film 40 using a well-known method such as dry etching, the piezoelectric film 40 is caused to have a pattern in which the plurality of protruding portions 41 are arranged (patterning process). Furthermore, as illustrated in FIG. 2E, an upper electrode forming process of forming the upper electrode 50 on each of the protruding portions 41 of the piezoelectric film 40 is performed, and as necessary, the lower surface of the substrate 10 is etched to reduce the thickness of the substrate 10, thereby completing the piezoelectric element 1.

By attaching the diaphragm 60 and the ink nozzle 70 to the piezoelectric element 1 (not illustrated), the ink jet recording head 3 is produced. Instead of attaching the diaphragm 60 and the ink nozzle 70 which are members independent from the substrate 10, a part of the substrate 10 may be processed into the diaphragm 60 and the ink nozzle 70. For example, in a case where the substrate 10 is a formed as a laminated substrate such as an SOI substrate, the diaphragm 60 and the ink nozzle 70 may be formed by etching the rear surface side of the substrate 10 to form the ink chamber 71 and processing the substrate itself.

As described above, the piezoelectric element 1 sequentially includes, on the silicon substrate 10, the titanium-containing adhesion layer 20, the lower electrode 30, and the piezoelectric film 40 including the PZT-based perovskite oxide represented by the general formula (P), and the adhesion layer component diffused from the titanium-containing adhesion layer 20 and the oxygen diffused from the piezoelectric film 40 side are included in the columnar structure film having the platinum group element of the lower electrode 30 as the primary component. In this configuration, since high adhesiveness between the silicon substrate 10 and the lower electrode 30 and high adhesiveness between the lower electrode 30 and the piezoelectric film 40 are achieved, peeling between the substrate and the electrodes and between the electrodes and the piezoelectric film is less likely to occur during long-term driving. Therefore, the piezoelectric element 1 becomes a PZT-based piezoelectric element having excellent long-term driving reliability.

In addition, according to the production method of the piezoelectric element of the present invention, since the oxygen diffusion process is performed before the formation of the piezoelectric film, the PZT-based piezoelectric element having high adhesiveness between the substrate and the lower electrode, high adhesiveness between the lower electrode and the piezoelectric film, and excellent long-term driving reliability can be easily produced.

“Ink Jet Recording Device”

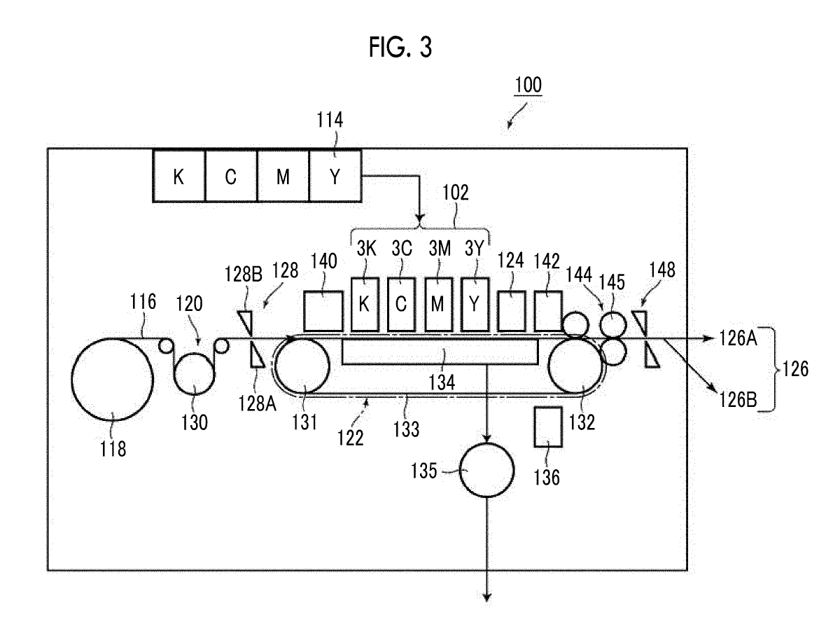

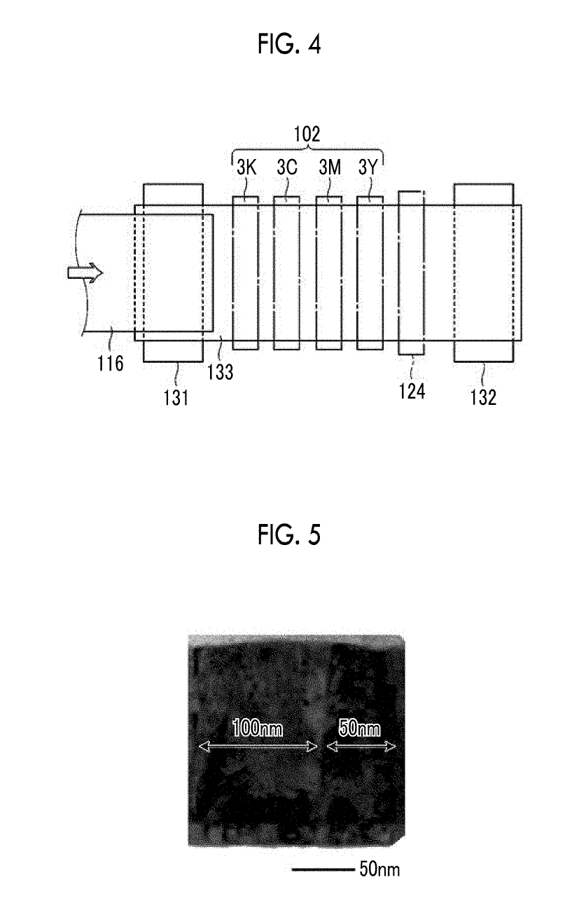

An example of the configuration of an ink jet recording device provided with the ink jet recording head 3 of the embodiment will be described with reference to FIGS. 3 and 4. FIG. 3 is an overall view of the device, and FIG. 4 is a partial top view.

An ink jet recording device 100 which is illustrated is schematically constituted by a printing unit 102 having a plurality of ink jet recording heads (hereinafter, simply referred to as “heads”) 3K, 3C, 3M, and 3Y respectively provided for ink colors, an ink storage/loading unit 114 which stores ink supplied to the heads 3K, 3C, 3M, and 3Y, a sheet feeding unit 118 which feds a recording sheet 116, a decurling unit 120 which eliminates curl of the recording sheet 116, an adsorption belt transporting unit 122 which is disposed to face a nozzle surface (ink discharge surface) of the printing unit 102 and transports the recording sheet 116 while holding the leveling of the recording sheet 116, a printing detection unit 124 which reads printing results of the printing unit 102, and a discharge unit 126 which discharges the printed recording sheet (printed matter) to the outside.

Each of the heads 3K, 3C, 3M, and 3Y constituting the printing unit 102 is the ink jet recording head 3 of the embodiment.

In the decurling unit 120, heat is applied to the recording sheet 116 by a heating drum 130 in a direction opposite to the curl direction, such that decurling is performed.

In an apparatus which uses a rolled sheet, as in FIG. 3, a cutter 128 for cutting is provided at the rear stage of the decurling unit 120, and the rolled sheet is cut into a desired size by the cutter. The cutter 128 is constituted by a fixed blade 128A having a length of equal to or greater than the transporting path width of the recording sheet 116, a round blade 128B which is moved along the fixed blade 128A, the fixed blade 128A is provided on the printing back surface side, and the round blade 128B is disposed on the printed surface side with the transporting path interposed therebetween. In an apparatus which uses a cut sheet, the cutter 128 is unnecessary.

The recording sheet 116 which is decurled and cut is sent to the adsorption belt transporting unit 122. The adsorption belt transporting unit 122 has a structure in which an endless belt 133 is wound between rollers 131 and 132 and is configured so that at least a portion which faces the nozzle surface of the printing unit 102 and a sensor surface of the printing detection unit 124 is a horizontal surface (flat surface).

The belt 133 has a width dimension wider than the width of the recording sheet 116, and a large number of suction holes (not illustrated) are formed on the belt surface. On the inside of the belt 133 suspended between the rollers 131 and 132, at a position at which the belt 133 faces the nozzle surface of the printing unit 102 and the sensor surface of the printing detection unit 124, an adsorption chamber 134 is provided. By suctioning the adsorption chamber 134 using a fan 135 to achieve a negative pressure, the recording sheet 116 on the belt 133 is adsorbed and held.

As power of a motor (not illustrated) of at least one of the rollers 131 and 132 around which the belt 133 is wound is transmitted, the belt 133 is driven in a clockwise direction in FIG. 3, and the recording sheet 116 held on the belt 133 is transported from the left to the right in FIG. 3.

When borderless printing is performed, ink is adhered onto the belt 133. Therefore, a belt cleaning unit 136 is provided at a predetermined position (an appropriate position excluding the printing region) on the outside of the belt 133.

On the upstream side of the printing unit 102 on the sheet transporting path formed by the adsorption belt transporting unit 122, a heating fan 140 is provided. The heating fan 140 heats the recording sheet 116 by blowing heating air toward the recording sheet 116 before being printed. Since the recording sheet 116 is heated immediately before printing, ink can be easily dried after being adhered.

The printing unit 102 is a so-called full line type head in which line type heads having a length corresponding to the maximum sheet width is disposed in a direction perpendicular to the sheet feeding direction (main scanning direction) (see FIG. 4). Each of the printing heads 3K, 3C, 3M, and 3Y is configured as a line type head in which a plurality of ink discharge ports (nozzles) are arranged to have a length greater than at least one side of the recording sheet 116 with the maximum size, which is an object of the ink jet recording device 100.

The heads 3K, 3C, 3M, and 3Y respectively corresponding to color inks are disposed in order of black (K), cyan (C), magenta (M), and yellow (Y) from the upstream side in the feeding direction of the recording sheet 116. By discharging color ink from each of the heads 3K, 3C, 3M, and 3Y while transporting the recording sheet 116, a color image is recorded on the recording sheet 116.

The printing detection unit 124 is formed as a line sensor or the like which images droplet ejection results of the printing unit 102 and detects discharge failure such as clogging of a nozzle from an image of the ejected droplets, which is read by the line sensor.

At the rear stage of the printing detection unit 124, a post-drying unit 142 which is formed as a heating fan or the like, which dries the printed image surface. Since it is preferable to avoid contact with the printed surface until the ink is dried after the printing, a heated air blowing method is preferable.

At the rear stage of the post-drying unit 142, a heating and pressurizing unit 144 is provided to control the glossiness of the image surface. In the heating and pressing unit 144, the image surface is pressed by a pressing roller 145 having predetermined surface uneven shapes while the image surface is heated, such that the uneven shapes are transferred onto the image surface.

The printed matter obtained in this manner is discharged from the discharge unit 126. It is preferable that a target image to be originally printed (a print of a target image) and a test print are separately discharged. In the ink jet recording device 100, sorting means (not illustrated) for switching between sheet discharge paths to sorting the printed matter of the original image and the printed matter of the test print to be respectively sent to discharge units 126A and 126B is provided.

In a case where the original image and the test print are simultaneously printed in parallel on a large sheet, a configuration in which a cutter 148 is provided to cut and separate a portion of the test print may be employed.

The ink jet recording device 100 is configured as described above.

(Design Change)

The present invention is not limited to the above-described embodiment, and various changes in design can be made without departing from the gist of the present invention.

### EXAMPLES

Examples according to the present invention and comparative examples will be described.

### Example 1

As a substrate, an SOI substrate (6-inch φ=about 150 mmφ)) in which a SiO₂ film having a thickness of about 300 nm and a Si active layer having a thickness of 15 μm were sequentially laminated on a (100) silicon substrate was prepared.

Using a sputtering apparatus, a Ti layer having a thickness of 20 nm and an Ir lower electrode having a thickness of 150 nm were sequentially formed on substantially the entire surface of the substrate under conditions of a substrate temperature of 200° C. and an Ar atmosphere at a degree of vacuum of 0.1 Pa. At this time, the distance between the substrate and a target was set to 10 cm, and the target power density was 7.5 W/cm².

The cross-section TEM image of the obtained Ir lower electrode was observed, and a columnar structure film was confirmed (FIG. 5). The main column diameter of the columnar structure film calculated from the TEM image was 50 to 100 nm.

Next, using the same apparatus, oxygen gas was caused to flow onto the substrate formed up to the Ir lower electrode under conditions of a substrate temperature of 450° C. for 5 minutes.

The wafer at this time was taken out before forming a PZT film and was analyzed by X-ray photoelectron spectroscopy (XPS) in the depth direction from the surface, and it could be seen that a Ti component was precipitated to the surface of the substrate.

In addition, it was confirmed by mapping of cross-section electron energy loss spectroscopy (EELS) that Ti was also present in the Ir electrode. This indicates that Ti as a component of the adhesion layer is diffused into the Ir electrode under the temperature heating condition. Similarly, the same was applied when TiW was used for the adhesion layer.

Subsequently, using a Pb_{1.3}(Zr_{0.52}Ti_{0.48})_{0.9}Nb_{0.1}O₃ target under conditions of an Ar/O₂ mixed atmosphere (O₂ volume fraction 3.0%) with a degree of vacuum of 0.5 Pa, a Nb-doped PZT piezoelectric film having a thickness of 2 μm was formed. The crystal structure of the obtained film was observed by X-ray diffraction (XRD), and peaks other than the perovskite structure were not observed. The film stress of the Nb-doped PZT piezoelectric film immediately after the film formation was calculated from the warping amount, and the calculated stress was 120 MPa.

Observation of a cross-section TEM image (HAADF-STEM image) in the vicinity of the Ir electrode by high-angle annular dark-field scanning transmission electron microscopy and mapping of the cross-section of the electrode by EELS were performed on the laminate formed on the SOI substrate up to the Nb-doped PZT film.

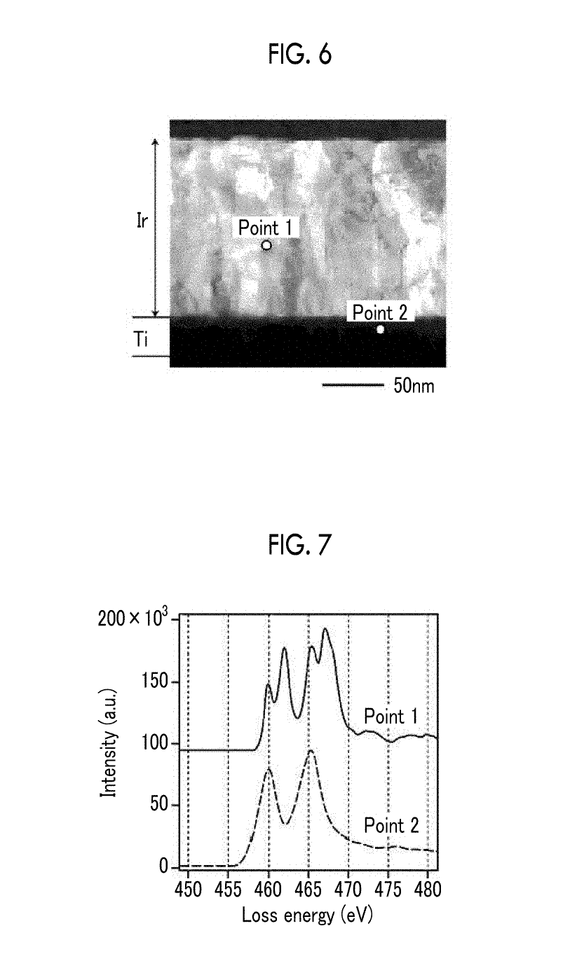

The HAADF-STEM image is shown in FIG. 6, and the mapping diagram is shown in FIG. 7. In FIG. 7, the peaks around 460 eV are separated at Point 1, and a peak is not separated at Point 2. According to Physical Review B 26 614-635 (1982) by Leapman, Grunes, and Fejes, this indicates that TiO₂ is formed at Point 1. That is, this indicates that Ti reaches the surface of the substrate from the adhesion layer through Ir, and oxygen is diffused from the surface of the electrode toward the adhesion layer side before the formation or during the formation of the PZT film and is bonded to Ti in the Ir electrode.

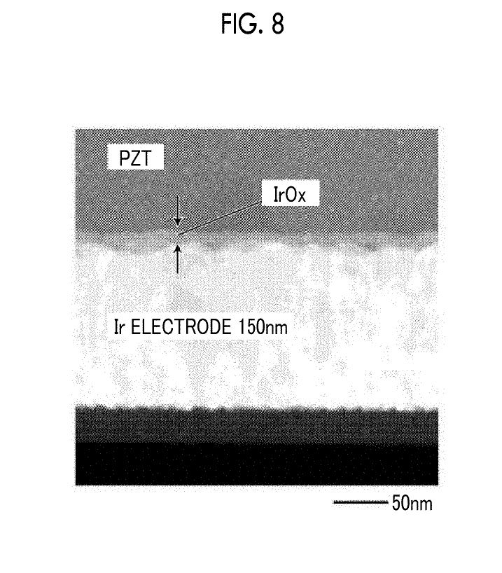

In addition, FIG. 8 shows the observation results of the cross-section TEM image (HAADF-STEM image) in the vicinity of the interface between the Ir electrode and the PZT layer. As shown in the figure, an oxide electrode layer (IrOₓ layer) with a high oxygen concentration was observed at the interface between the Ir electrode and the piezoelectric body. It was confirmed by an energy-dispersive X-ray spectrometer (EDS) with a focused spot diameter that IrOₓ is the primary component. Although there is a possibility that Ti may be included in the oxide electrode layer, Ti could not be accurately analyzed due to the presence of PZT.

Last, the lower surface side of the SOI substrate was subjected to reactive-ion etching (RIE) to form an ink chamber of 500 μm×500 μm, the active layer (15-μm thick) of the SOI substrate was used as a diaphragm, an ink nozzle having the diaphragm, the ink chamber, and an ink discharge port was formed by processing the SOI substrate itself, thereby obtaining the piezoelectric element of the present invention.

The piezoelectric element was driven at 20 V satisfactorily. The piezoelectric constant d₃₁ of the piezoelectric body was about −230 pm/V. Regarding the “piezoelectric constant d₃₁”, the displacement was measured using a laser doppler vibrometer, and the value was calculated by a finite element method to which the diaphragm size, the dimensions of the layer configuration, and the materials property values are input.

After 100 hours of driving, the adhesiveness between the electrode layer and the underlayer and the overlayer thereof was checked, and there was no change in the adhesiveness in a tape test.

As described above, it was confirmed that the PZT-based piezoelectric element which has improved adhesiveness between the substrate and the lower electrode and improved adhesiveness between the lower electrode and the piezoelectric film due to the titanium diffused from the adhesion layer and the oxygen diffused from the piezoelectric film side, which are bonded together in the lower electrode, does not easily cause peeling between the substrate and the electrodes and between the electrodes and the piezoelectric film during long-term driving, and thus has excellent long-term driving reliability can be achieved.

### Example 2

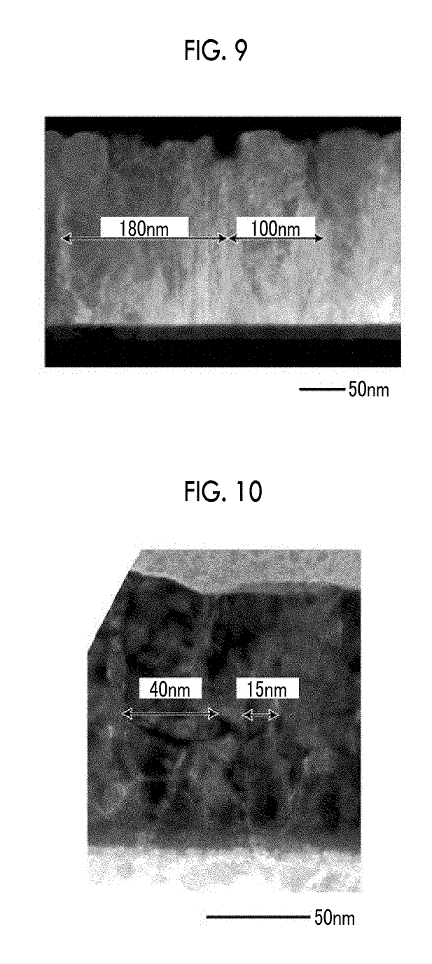

A Nb-doped PZT piezoelectric film was formed in the same manner as in Example 1 except that the distance between the target and the substrate during the film formation of the Ir lower electrode was set to 5 cm, and the amount of oxygen and the piezoelectric constant were measured in the same manner as in Example 1. A cross-section SEM image after the film formation of the Ir lower electrode is shown in FIG. 9. The main column diameter of the columnar structure film calculated from the cross-section SEM image was 100 nm to 180 nm.

The wafer at this time was taken out before forming a PZT film and subjected to XPS analysis in the depth direction from the surface, and it could be seen that a Ti component was precipitated to the surface of the substrate. However, the precipitated amount was clearly smaller than that of Example 1. In addition, it was confirmed by mapping of cross-section EELS that Ti was also present in the Ir electrode. It was thought that the amount of Ti at this time was also smaller than that in Example 1. Similarly, the same was applied when TiW was used for the adhesion layer.

It is thought that the reason why the amount of Ti precipitated to the surface is small is because the main column diameter of the columnar structure film of the Ir electrode is large, the amount of grain boundaries is substantially small, and the amount of Ti that passes through the grain boundaries decreases. For the same reason, it is thought that a smaller amount of Ti is present because a smaller amount of grain boundaries are present in the cross-section of Ir.

The Ir electrode after forming the PZT film was analyzed by secondary ion mass spectrometry (SIMS), and the amount of oxygen in the film was analyzed in the depth direction. Oxygen was observed down to about 100 nm from the surface.

A piezoelectric element was produced in the same manner as in Example 1 and the piezoelectric constant and the adhesiveness of the electrode layer after driving for 100 hours were evaluated in the same manner as in Example 1. A piezoelectric constant substantially equivalent to that in Example 1 was obtained, and there was no change in the adhesiveness in the tape test.

### Comparative Example 1

A Nb-doped PZT piezoelectric film was formed in the same manner as in Example 1 except that the distance between the substrate and the target during the film formation of the Ir lower electrode was set to 15 cm, and the amount of oxygen was measured in the same manner as in Example 1. The main column diameter of the columnar structure film calculated from the cross-section TEM image (FIG. 10) after the film formation of the Ir lower electrode was 40 nm or less.

The laminate formed on the SOI substrate up to the Nb-doped PZT film was analyzed down to the titanium-containing adhesion layer from the surface of the Nb-doped PZT film by SIMS, and the amount of oxygen in the film was measured. As a result, it was observed that oxygen from the piezoelectric film side was diffused from the Nb-doped PZT interface into the lower electrode directed toward the substrate.

In addition, when the cross-section of the laminate was analyzed by EELS, it was confirmed that titanium was present up to the surface of the lower electrode (piezoelectric body interface) in the lower electrode. However, the amount of titanium was clearly larger than that in Examples 1 and 2. It is presumed that this is caused by an excessive amount of grain boundaries of the Ir lower electrode.

It is thought that the size of the average main column diameter of the Ir electrode is varied with the distance from the substrates by the difference in energy between sputtered particles. A method of changing the average main column diameter of the Ir electrode is not limited to the method of changing the distance between the target and the substrates, and various methods such as methods of changing the pressure, the input power, the substrate temperature, and the like may be employed.

In addition, it could be seen from the cross-section TEM image of the laminate that a pyrochlore layer of about 100 nm was grown on the interface between the lower electrode and the Nb-doped PZT film, and a perovskite layer is grown thereon. A piezoelectric element was produced in the same manner as in Example 1, and the piezoelectric constant was measured. d₃₁ was about −140 pm/V. Furthermore, after the driving, the adhesiveness to the underlayer and the overlayer of the electrode layer was checked. There was no change in the adhesiveness in a tape test. Although the mechanism of the growth of the pyrochlore phase is not clear, it is presumed that Ti precipitated to the surface of the substrate become the nucleus of PZT growth, but in a case of an excessive amount of Ti, the composition is shifted at the initial stage of growth and crystals other than PZT are likely to be formed.

### Comparative Example 2

A Nb-doped PZT piezoelectric film was formed in the same manner as in Example 1 except that the substrate temperature during the film formation of the Ir lower electrode was set to 550° C., and the amount of oxygen was measured in the same manner as in Example 1. The main column diameter of the columnar structure film calculated from the cross-section TEM image after the film formation of the Ir lower electrode was 250 nm or more.

The laminate formed on the SOI substrate up to the Nb-doped PZT film was analyzed down to the titanium-containing adhesion layer from the surface of the Nb-doped PZT film by SIMS, and the amount of oxygen in the film in the depth direction was measured. As a result, it was observed that oxygen from the piezoelectric film side was diffused from the Nb-doped PZT interface into a depth of about 20 nm in the lower electrode directed toward the substrate.

In addition, when the cross-section of the laminate was analyzed by EELS, it was confirmed that a slight amount of titanium was present up to the surface of the lower electrode (piezoelectric body interface) in the lower electrode. It is presumed that this is caused by an excessively small amount of grain boundaries of the Ir lower electrode.

In addition, from the cross-section TEM image of the laminate, substantially no pyrochlore layer was observed at the interface between the lower electrode and the Nb-doped PZT film. A piezoelectric element was produced in the same manner as in Example 1 and was driven at 20 V. After 100 hours of the driving, the adhesiveness to the underlayer and the overlayer of the electrode layer was checked. Thereafter, the adhesiveness to the PZT film was checked in a tape test, and it was confirmed that a part of the film peeled off and the durability was poor.

### Comparative Example 3

A Nb-doped PZT piezoelectric film was formed in the same manner as in Example 1 except that the oxygen diffusion process was not performed before the film formation of the Nb-PZT piezoelectric film, and the amount of oxygen was measured in the same manner as in Example 1.

The laminate formed on the SOI substrate up to the Nb-doped PZT film was analyzed down to the titanium-containing adhesion layer from the surface of the Nb-doped PZT film by SIMS, and the amount of oxygen in the film was measured. As a result, substantially no oxygen diffused was observed in the lower electrode directed from the Nb-doped PZT interface toward the substrate, and no Ir oxide layer was observed at the interface between the Ir lower electrode and the Nb-PZT piezoelectric film.

A piezoelectric element was produced in the same manner as in Example 1 and was driven at 20 V for 100 hours. After the driving, the adhesiveness to the underlayer and the overlayer of the electrode layer was checked. It was confirmed that a part of the film peeled off and the durability was poor.

### Reference Example

As a reference example, a PZT film which had the same structure as Comparative Example 2 and was not doped with Nb was formed. The stress of the PZT film at this time was about 110 MPa. A peeling test was conducted after the obtained film was driven in the same manner, but there was no problem.

From this, it could be seen that the adhesiveness was improved due to the relationship between the diffusion of Ti, the bonding to oxygen in the Ir electrode, and the stress of the PZT film.

TABLE 1

| | Main column | | Oxygen | PZT film | |
|---|---|---|---|---|---|
| | diameter | Ti diffusion | diffusion | quality | Adhesiveness |
| Example 1 | 50 nm to 100 nm | Present | Present | Good | Good |
| Example 2 | 100 nm to 180 nm | Present | Present | Good | Good |
| | | (lower degree | | | |
| | | than Example 1) | | | |
| Comparative | 40 nm or less | Present, | Present | No Good | Good |
| Example 1 | | high degree | | (pyrochlore | |
| | | | | 100 nm) | |
| Comparative | 250 nm or less | Low degree | Present | Good | No Good |
| Example 2 | | | | | |
| Comparative | 50 nm to 100 nm | Present | Absent | Good | No Good |
| Example 3 | | | | | |

The piezoelectric element of the present invention can be preferably used in a piezoelectric actuator mounted in a magnetic recording and reproducing head, a microelectromechanical systems (MEMS) device, a micropump, an ultrasound probe, or the like, and in a ferroelectric element such as a ferroelectric memory.

What is claimed is:

1. A piezoelectric element comprising:
a titanium-containing adhesion layer, a lower electrode, a piezoelectric film including a perovskite oxide represented by the following general formula (P), and an upper electrode, which are sequentially provided on a silicon substrate,
wherein the lower electrode includes a columnar structure film including a large number of columnar crystals which are grown from a surface of the titanium-containing adhesion layer and have a platinum group element as a primary component, and an adhesion layer component diffused from the titanium-containing adhesion layer and oxygen diffused from the piezoelectric film side, which are present in the columnar structure film, and
a main column diameter of the columnar crystal of the columnar structure film is 50 nm or more and 200 nm or less,
Aₐ(Zrₓ,Ti_{y},M_{b-x-y})_{b}O_{c} (P)
in the formula, A is an element in A-site and is at least one element including Pb, M is one or two or more metal elements, 0<x<b, 0<y<b, and 0≦b-x-y are satisfied, and a:b:c=1:1:3 is standard, and the molar ratio may be deviated from the standard value in a range in which a perovskite structure is able to be obtained.

2. The piezoelectric element according to claim 1,
wherein the adhesion layer component and the oxygen in the columnar structure film are bonded together.

3. The piezoelectric element according to claim 1,
wherein an oxide layer of the platinum group element is formed on the surface of the lower electrode on the piezoelectric film side.

4. The piezoelectric element according to claim 3,
wherein a thickness of the oxide layer is 20 nm or less.

5. The piezoelectric element according to claim 1,
wherein the platinum group element is iridium.

6. The piezoelectric element according to claim 1,
wherein the titanium-containing adhesion layer is a metal layer.

7. The piezoelectric element according to claim 6,
wherein the titanium-containing adhesion layer is a titanium layer or a titanium tungsten layer.

8. The piezoelectric element according to claim 1,
wherein Nb is included as the M.

9. The piezoelectric element according to claim 1,
wherein a stress of the piezoelectric film is 120 MPa or higher.

10. An actuator comprising:
the piezoelectric element according to claim 1.

11. A liquid discharge apparatus comprising:
the piezoelectric element according to claim 1; and
a liquid discharge member which is provided integrally with or separately from the piezoelectric element,
wherein the liquid discharge member has a liquid storage chamber which stores a liquid, and a liquid discharge port through which the liquid is discharged from the liquid storage chamber to the outside.

12. A production method of a piezoelectric element in which a titanium-containing adhesion layer, a lower electrode including a columnar structure film that has a main column diameter of 50 nm or more and 200 nm or less and has a platinum group element as a primary component, a piezoelectric film including a perovskite oxide represented by the following general formula (P), and an upper electrode, which are sequentially provided on a silicon substrate, the method comprising:
a lower electrode forming process of sequentially forming, on the silicon substrate, the titanium-containing adhesion layer and the lower electrode;
an oxygen diffusion process of diffusing oxygen from the surface side of the lower electrode into the lower electrode; and
a piezoelectric film forming process of forming the piezoelectric film on the surface through a sputtering method,
the oxygen diffusing step being a step that causes oxygen gas to flow onto the surface
Aₐ(Zrₓ,Ti_{y},M_{b-x-y})_{b}O_{c} (P)
in the formula, A is an element in A-site and is at least one element including Pb, M is one or two or more metal elements, 0<x<b, 0<y<b, and 0≦b-x-y are satisfied, and a:b:c=1:1:3 is standard, and the molar ratio may be deviated from the standard value in a range in which a perovskite structure is able to be obtained.

13. The production method of a piezoelectric element according to claim 12,
wherein a constituent element of the titanium-containing adhesion layer is diffused into the lower electrode to precipitate the constituent element on the surface before performing the piezoelectric film forming process.

14. A method for producing a piezoelectric element in which a titanium-containing adhesion layer, a lower electrode including a columnar structure film that has a main column diameter of 50 nm or more and 200 nm or less and has a platinum group element as a primary component, a piezoelectric film including a perovskite oxide represented by the following general formula (P), and an upper electrode, which are sequentially provided on a silicon substrate, the method comprising:
a lower electrode forming process of sequentially forming, on the silicon substrate, the titanium-containing adhesion layer and the lower electrode;
an oxygen diffusion process of diffusing oxygen from the surface side of the lower electrode into the lower electrode; and
a piezoelectric film forming process of forming the piezoelectric film on the surface through a sputtering method,
constituent elements of the titanium containing adhesion layer being diffused on the lower electrode before executing the piezoelectric film forming process, to cause the constituent elements to precipitate on the surface;
Aₐ(Zrₓ,Ti_{y},M_{b-x-y})_{b}O_{c} (P)
wherein A is an element in A-site and is at least one element including Pb, M is one or two or more metal elements, 0<x<b, 0<y<b, and 0≦b-x-y are satisfied, and a:b:c=1:1:3 is standard, and the molar ratio may be deviated from the standard value in a range in which a perovskite structure is able to be obtained.
